(19) United States
(12) Patent Application Publication
(10) Pub. No.: US 2023/0411230 A1
(43) Pub. Date: Dec. 21, 2023

(54) ELECTRONIC DEVICE AND MANUFACTURING METHOD THEREOF

(71) Applicant: InnoLux Corporation, Miao-Li County (TW)

(72) Inventors: Cheng-Chi WANG, Miao-Li County (TW); Cheng-Hsien HO, Miao-Li County (TW); Kuo-Sheng YEH, Miao-Li County (TW); Ching-Wei CHEN, Miao-Li County (TW); Chin-Ming HUANG, Miao-Li County (TW)

(21) Appl. No.: 17/815,297

(22) Filed: Jul. 27, 2022

(30) Foreign Application Priority Data
Jun. 21, 2022 (CN) 202210703502.5

(51) Int. Cl. H01L 23/31; H01L 23/00; H01L 21/56

(52) U.S. Cl. CPC H01L 23/3135; H01L 24/20; H01L 24/24; H01L 24/25; H01L 21/561; H01L 21/568; H01L 23/3121; H01L 2224/214; H01L 2224/244; H01L 2224/211; H01L 2224/24137; H01L 2224/25175; H01L 2224/19; H01L 2224/82101; H01L 24/82

(57) ABSTRACT

An electronic device includes a protective layer, an electronic unit and at least one anchor structure disposed in the protective layer, and a connecting member disposed on the protective layer. The electronic unit includes a first electronic unit and a second electronic unit that are electrically connected through the connecting member. The at least one anchor structure is between the first electronic unit and the second electronic unit. The connecting member has a first conductive layer, and the first conductive layer contacts the surface of the first electronic unit, the surface of the anchor structure and the surface of the protective layer.

### CROSS REFERENCE TO RELATED APPLICATIONS

This application claims priority of China Patent Application No. 202210703502.5, filed on Jun. 21, 2022, the entirety of which is incorporated by reference herein.

### BACKGROUND OF THE INVENTION

### Field of the Invention

The present disclosure relates to an electronic device and a manufacturing method thereof, and, in particular, to an electronic device comprising electronic units and a connecting member that serves to electrically connect the electronic units, and a manufacturing method thereof.

### Description of the Related Art

In order to protect electronic units, a packaging process is usually performed after forming the electronic units on a substrate, to form an electronic device with a packaging structure. The package structure, for example, can insulate the electronic units from the effects of temperature and humidity in the environment, and can prevent physical or mechanical damage to the electronic units from external impact.

With the development of the semiconductor industry, the size of electronic devices continues to shrink and the number of electronic units disposed in each unit area of the electronic device continues to increase. As the size of the electronic devices shrinks and the number of electronic units increases, the process of manufacturing the electronic devices requires a higher degree of accuracy in the alignment of these electronic units. Positional deviations of the electronic units in any stage of the process of manufacturing the electronic devices will result in a failure to form good electrical connections between adjacent electronic units. In the technology currently in use, the accuracy of electronic unit alignment can be honed by improving the accuracy of the bonding alignment of the electronic unit and the substrate. However, this improved bonding alignment cannot prevent the electronic units bonded to the substrate from positional deviations during subsequent processes in forming the packaging adhesive.

### BRIEF SUMMARY OF THE INVENTION

In view of the above-mentioned problems, the present disclosure provides an electronic device and a manufacturing method thereof, wherein the electronic device has an anchor structure that can prevent the position of the electronic unit therein from shifting during the formation of the protective layer.

An embodiment of the present disclosure provides an electronic device comprising a protective layer, an electronic unit and at least one anchor structure disposed in the protective layer, and a connecting member disposed on the protective layer. The electronic unit comprises a first electronic unit and a second electronic unit that are electrically connected through the connecting member. The at least one anchor structure is between the first electronic unit and the second electronic unit. The connecting member has a first conductive layer, and the first conductive layer contacts the surface of the first electronic unit, the surface of the anchor structure and the surface of the protective layer.

An embodiment of the present disclosure provides an electronic device comprising a protective layer, an electronic unit, a first anchor structure, a second anchor structure and a connecting portion disposed in the protective layer, and a connecting member disposed on the protective layer. The electronic unit comprises a first electronic unit and a second electronic unit that are electrically connected through the connecting member. The first anchor structure and the second anchor structure are between the first electronic unit and the second electronic unit. The connecting portion connects the first anchor structure and the second anchor structure, and is combined with the first anchor structure and the second anchor structure to form a recessed portion having inclined sidewalls or curved sidewalls.

In addition, an embodiment of the present disclosure provides a manufacturing method of an electronic device, comprising: providing a substrate; providing a first electronic unit and a second electronic unit on the substrate; providing at least one anchor structure between the first electronic unit and the second electronic unit; providing a protective layer surrounding the at least one anchor structure, the first electronic unit, and the second electronic unit; and providing a connecting member electrically connecting the first electronic unit and the second electronic unit.

An embodiment of the present disclosure provides a manufacturing method of an electronic device, comprising: providing a substrate; providing at least one anchor on the substrate; providing a first electronic unit and a second electronic unit on the substrate, wherein the at least one anchor structure is between the first electronic unit and the second electronic unit; providing a protective layer surrounding the at least one anchor structure, the first electronic unit, and the second electronic unit; and providing a connecting member electrically connecting the first electronic unit and the second electronic unit.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates a cross-sectional schematic view of an electronic device according to an embodiment of the present disclosure.

FIG. 2 illustrates a cross-sectional schematic view of an electronic unit according to an embodiment of the present disclosure.

FIGS. 3A to 3C are schematic diagrams illustrating the configuration of the anchor structure in the electronic device according to the embodiment of the present disclosure.

FIG. 4 illustrates a cross-sectional schematic view of an electronic device according to another embodiment of the present disclosure.

FIG. 5 illustrates a cross-sectional schematic view of an electronic device according to another embodiment of the present disclosure.

FIG. 6 illustrates a cross-sectional schematic view of an electronic device according to another embodiment of the present disclosure.

FIG. 7 is a flowchart illustrating a manufacturing method of an electronic device according to an embodiment of the present disclosure.

FIGS. 8A, 9A, and 10A are top schematic views of the electronic device in intermediate stages of the manufacturing method of the electronic device according to an embodiment of the present disclosure.

FIGS. 8B, 9B, 9C, and 10B to 13 are cross-sectional schematic views of an electronic device in intermediate stages of the manufacturing method of the electronic device according to an embodiment of the present disclosure.

FIG. 14 is a flowchart illustrating a manufacturing method of an electronic device according to another embodiment of the present disclosure.

FIGS. 15 and 16 are top schematic views of the electronic device in intermediate stages of the manufacturing method of the electronic device according to another embodiment of the present disclosure.

### DETAILED DESCRIPTION OF THE INVENTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

Throughout the present specification and the appended claims, certain terms may be used to refer to specific elements. It should be understood by those skilled in the art that the same elements may be referred to by different names. The present disclosure does not intend to distinguish between those elements that have the same function but have different names. In the specification and claims below, the words “comprises” and “includes” are open-ended terms and should therefore be interpreted to mean “comprises but not limited to . . . ”.

It should be understood that the use of ordinal terms such as “first”, “second”, etc., in the specification and claims to modify an element does not by itself connote any priority, precedence, or order of one claim element over another or the temporal order in which it is formed, but are used merely as labels to distinguish one claim element having a certain name from another element having the same name to distinguish the claim elements. Therefore, the first element in the specification may be referred as the second element in the claims.

Directional terms mentioned in the following examples, such as: up, down, left, right, front or back, etc., are only references to the directions in the attached drawings. Accordingly, the directional terms used are for illustrative purposes and are not intended to limit the present disclosure. It is important to understand that the components specifically described or illustrated may exist in various forms known to those of skill in the art.

Some embodiments of the disclosure are described. Additional operations can be provided before, during, and/or after the stages described in these embodiments. Some of the stages that are described can be replaced or eliminated for different embodiments. Although some embodiments are discussed with steps performed in a particular order, these steps may be performed in another logical order.

Furthermore, when an element or layer is referred to as being “on,” or “connected to,” another element or layer, it may be directly on or connected to the other element or layer or intervening elements or layers may be present (in the examples which are indirectly on or connected to). When, however, an element or layer is referred to as being “directly on,” or “directly connected to,” another element or layer, there are no intervening elements or layers present. When an element or layer is referred to as being “coupled to” another element or layer, it may include the case where “the element is electrically connected to another element with intervening elements may be present” or the case where “the element is directly electrically connected to another element with no intervening elements present”. When an element is referred to as being “directly coupled to” another element, it refers to the case where “the element is directly electrically connected to another element with no intervening elements present”.

It will be understood that, the term “about”, “substantially”, as used herein usually indicates a value of a given value or range that varies within 10%, within 5%, within 3%, within 2%, within 1%, or within 0.5%. The value given here are approximate value, i.e., “about”, or “substantially”, may be implied without specifying “about”, or “substantially”. It will be further understood that the expression “between a first value and a second value” used herein to indicate a specific range including the said first value, the said second value, and values between thereof.

Furthermore, it should be understood that according to the embodiments of the present disclosure, the width, thickness or height of the elements or the spacing or distance between the elements may be measured using a scanning electron microscope (SEM), an optical microscope (OM), an alpha-step (α-step), an ellipsometer, or other suitable means. In detail, according to some embodiments, a scanning electron microscope may be used to obtain a cross-sectional image of the structure of the elements to be measured and to measure the width, thickness, height or angle of each element, the spacing or distance between the elements.

Unless otherwise defined, all terms (including technical and scientific terms) used herein have the same meaning as commonly understood by a person skilled in the art to which the disclosure pertains. It will be further understood that terms, such as those defined in commonly used dictionaries, should be interpreted as having a meaning consistent with the relevant technology and the context or background of this disclosure and will not be interpreted in an idealized or overly formal sense unless expressly so defined herein.

The electronic device of the present disclosure may include a display device, an antenna device, a sensing device, a touch display a packaging device a curved display, or a free shape display, but not limited there to. The electronic device may be a bendable or flexible electronic device, but the present disclosure is not limited there to. The antenna device maybe, for example, a liquid crystal antenna, but not limited there to. The antenna device may include, for example, an antenna splicing device, but is not limited thereto. The packaging device may be used for Wafer-Level Package (WLP) technology or Panel-Level Package (WLP) technology, such as chip first or RDL first processes, but not limited to these. It should be noted that the electronic device can be, but not limited to, any combination of the aforementioned devices. In addition, a shape of the electronic device may be a rectangle, a circle, a polygon, a shape with curved edges, or other suitable shape. The electronic device may include electronic elements. The electronic elements may include passive elements and/or elements, such as capacitors, resistors, inductors, diodes, transistors, etc. The diodes may include light-emitting diodes or photoelectric diodes. The light-emitting diodes may include, for example, organic light-emitting diodes (OLED), mini light-emitting diodes (mini LED), micro light-emitting diodes (micro LED), or quantum dot light-emitting diodes (quantum dot LED), but not limited to thereof. The electronic devices may have peripheral systems such as drive systems, control systems, light source systems, shelf systems, etc. to support display devices, antenna devices, or splicing devices. The packaging device will be used as an example to illustrate the contents of the present disclosure, but this disclosure is not limited thereof.

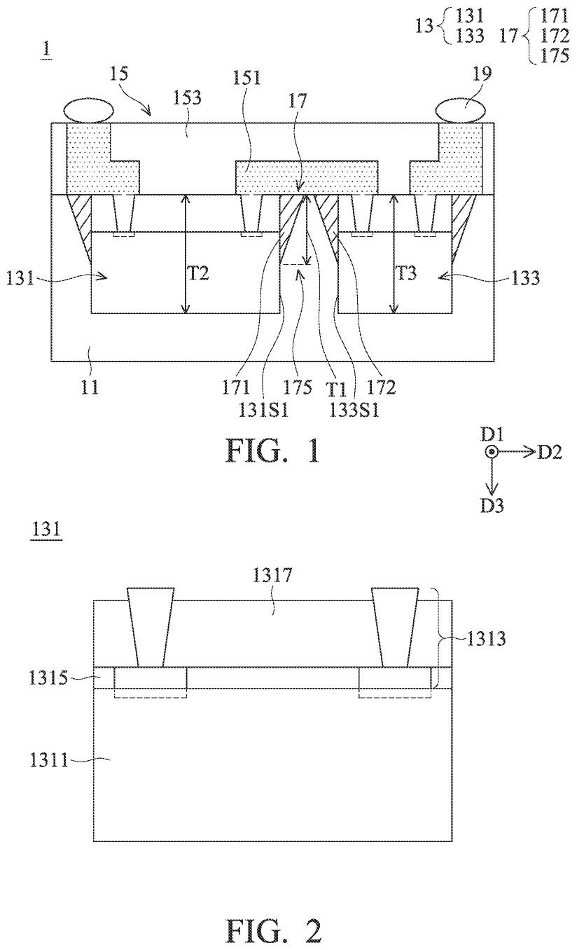

FIG. 1 illustrates a cross-sectional schematic view of an electronic device 1 according to an embodiment of the present disclosure. As shown in FIG. 1, the electronic device 1 includes a protective layer 11, an electronic unit 13, an anchor structure 17, and a connecting member 15. The electronic unit 13 includes a first electronic unit 131 and a second electronic unit 133. The first electronic unit 131 has a first side 131S1 and the second electronic unit 133 has a first side 133S1. The first side 131S1 of the first electronic unit 131 is opposite to first side 133S1 of the second electronic unit 133. The anchor structure 17 is between the first electronic unit 131 and the second electronic unit 133. The first electronic unit 131, the second electronic unit 133, and the anchor structure 17 are disposed in the protective layer 11, and the connecting member 15 is disposed on the protective layer 11. The first electronic unit 131 and the second electronic unit 133 are electrically connected through the connecting member 15. In some embodiments, the electronic device 1 may further include a connecting pad 19 disposed on the connecting member 15. The connecting pad 19 may connect the electronic device 1 to other electronic elements or external circuits. In some embodiments, the protective layer 11 may include any material that can be used as an encapsulation material. In some embodiments, the protective layer 11 may include epoxy resins. The surface of the first electronic unit 131, the surface of the second electronic unit 133, the surface of the anchor structure 17 and the surface of the protective layer 11 may be coplanar. The risk of interface cracking can be lower by the above arrangement, thereby improving the reliability of the electronic device. The protective layer 11 is in direct contact with at least part of the side of the first electronic unit 131 and at least part of the side of the second electronic unit 133. By directly contacting the at least part of the side of the first electronic unit 131 and the at least part of the side of the second electronic unit 133, the protective layer 11 can reduce the influence of moisture and oxygen in the environment on the first electronic unit 131 and the second electronic unit 133. Therefore, the service life and reliability of the first electronic unit 131 and the second electronic unit 133 can be improved, but the present disclosure is not limited thereto.

FIG. 2 illustrates a cross-sectional schematic view of the first electronic unit 131 according to an embodiment of the present disclosure. The structure of the first electronic unit 131 will be described below with reference to FIG. 1 and FIG. 2. As shown in FIG. 2, the first electronic unit 131 includes a chip unit 1311, a first insulating layer 1315, and a second Insulating layer 1317. The chip unit 1311 includes a plurality of bonding pads 1313. The second insulating layer 1317 is disposed on the chip unit 1311, the first insulating layer 1315 is disposed between the chip unit 1311 and the second insulating layer 1317, and the first insulating layer 1315 and the second insulating layer 1317 expose the bonding pads 1313. According to some embodiments, a passivation layer may be included between the chip unit 1311 and the first insulating layer 1315. The material of the passivation layer may be different from that of the first insulating layer 1315, and the thickness of the passivation layer may be smaller than the thickness of the first insulating layer 1315. The second insulating layer 1317 and the first insulating layer 1315 may have the same or different thicknesses. In some embodiments, the thickness of the second insulating layer 1317 may be greater than the thickness of the first insulating layer 1315, as shown in FIG. 2, but the present disclosure is not limited thereto. The first insulating layer 1315 and the second insulating layer 1317 may include the same or different materials. In some embodiments, the first insulating layer 1315 and the second insulating layer 1317 may independently include materials with Young's modulus between 1000 Mpa and 20000 Mpa. In some embodiments, the first insulating layer 1315 and the second insulating layer 1317, respectively, may include materials with a coefficient of linear thermal expansion (CTE) between 3 and 60 ppm/K. The materials included in the first insulating layer 1315 and the second insulating layer 1317 may be organic insulating materials, inorganic insulating materials, or a combination thereof. Examples of the materials included in the first insulating layer 1315 and the second insulating layer 1317 may independently include polymer-based dielectric films, organic polymer films, Ajinomoto Build-up Film (ABF), and any combination thereof, but the present disclosure is not limited thereto. In some embodiments, the first insulating layer 1315 and the second insulating layer 1317 may independently include epoxy resin, benzocyclobutene (BCB), polyimide (PI), polybenzoxazole (PBO), silicon oxide (SiOₓ), silicon nitride (SiNₓ), silicon oxynitride (SiOₓN_{y}), photosensitive polyimide (Photosensitive PI, PSPI), and/or any combination thereof. The second electronic unit 133 and the first electronic unit 131 have a similar structure. That is, similar to the first electronic unit 131, the second electronic unit 133 also includes a chip unit, a first insulating layer, and a second insulating layer. The said chip unit includes a plurality of bonding pads, and the materials, structures and configurations of the chip unit, the first insulating layer, and the second insulating layer in the second electronic unit 133 are similar to those described above with reference to the first electronic unit 131. The description thereof will not be repeated here. In some embodiments, the chip unit in the first electronic unit 131 and the chip unit in the second electronic unit 133 may have the same or different functions.

The connecting member 15 is disposed on the protective layer 11, the first electronic unit 131, the second electronic unit 133, and the anchor structure 17. The second insulating layer 1317 is disposed between the first insulating layer 1315 and the connecting member 15. The connecting member 15 electrically connects the first electronic unit 131 and the second electronic unit 133 through the bonding pad 1313 of the first electronic unit 131 and the bonding pad of the second electronic unit 133. In some embodiments, the connecting member 15 may include a first conductive layer 151 and an insulating layer 153. In some embodiments, the insulating layer 153 in connecting member 15 may include any insulating material different from the protective layer 11. In some embodiments, the first conductive layer 151 may include metallic conductive materials (e.g., aluminum (Al), copper (Cu), molybdenum (Mo), titanium (Ti), platinum (Pt), iridium (Ir), nickel (Ni), chromium (Cr), silver (Ag), gold (Au), tungsten (W), or an alloy thereof) and/or metallic compound conductive materials (e.g., materials comprising compounds, alloys or any combination thereof including aluminum (Al), copper (Cu), molybdenum (Mo), titanium (Ti), platinum (Pt), iridium (Ir), nickel (Ni), chromium (Cr), silver (Ag), gold (Au), tungsten (W), magnesium (Mg), or any combination thereof, but this disclosure is not limited to the above. In some embodiments, the first conductive layer 151 may include copper and a titanium copper alloy (TiCu). In some embodiments, the connecting member 15 may be, for example, a redistribution layer. The connecting member 15 may include thin film transistors, capacitors, diodes, or other suitable active or passive elements, but not limited thereto.

In some embodiments, the electronic device 1 may further include a bonding pad 19. The bonding pad 19 can be disposed above the first conductive layer 151 of the connecting member 15 and electrically connected with the first conductive layer 151 to electrically connect the first electronic unit 131 and the second electronic unit 133 to other electronic elements or external circuits. In some embodiments, the bonding pad 19 may include metallic conductive materials (e.g., aluminum (Al), copper (Cu), molybdenum (Mo), titanium (Ti), platinum (Pt), iridium (Ir), nickel (Ni), chromium (Cr), silver (Ag), gold (Au), tungsten (W), or an alloy thereof) and/or metallic compound conductive materials (e.g., materials comprising compounds, alloys or any combination thereof including aluminum (Al), copper (Cu), molybdenum (Mo), titanium (Ti), platinum (Pt), iridium (Ir), nickel (Ni), chromium (Cr), silver (Ag), gold (Au), tungsten (W), magnesium (Mg), or any combination thereof, but this disclosure is not limited to the above. In some embodiments, the bonding pad 19 may include the same conductive material as the first conductive layer 151, but the present disclosure is not limited thereto.

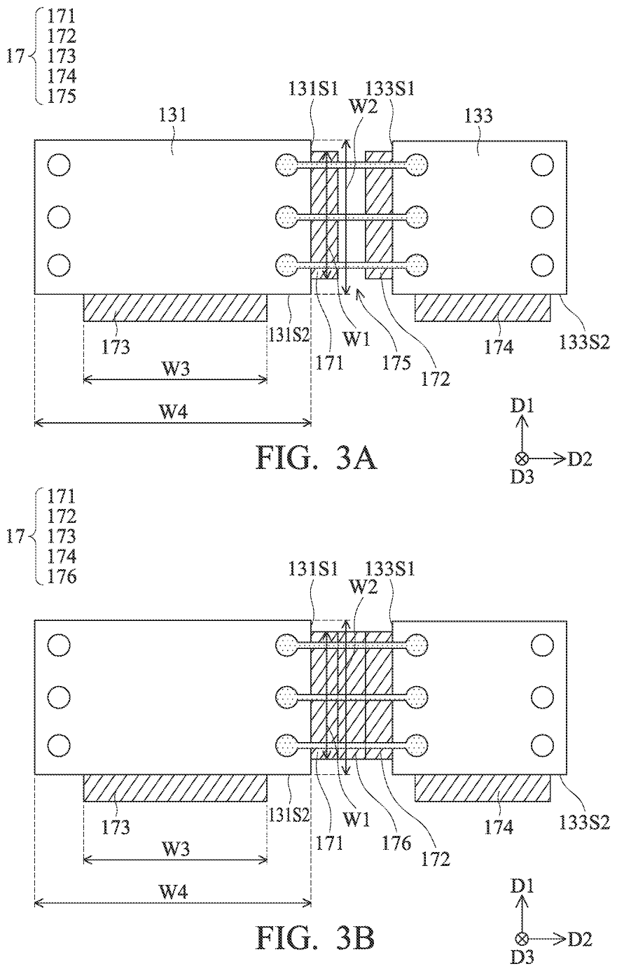

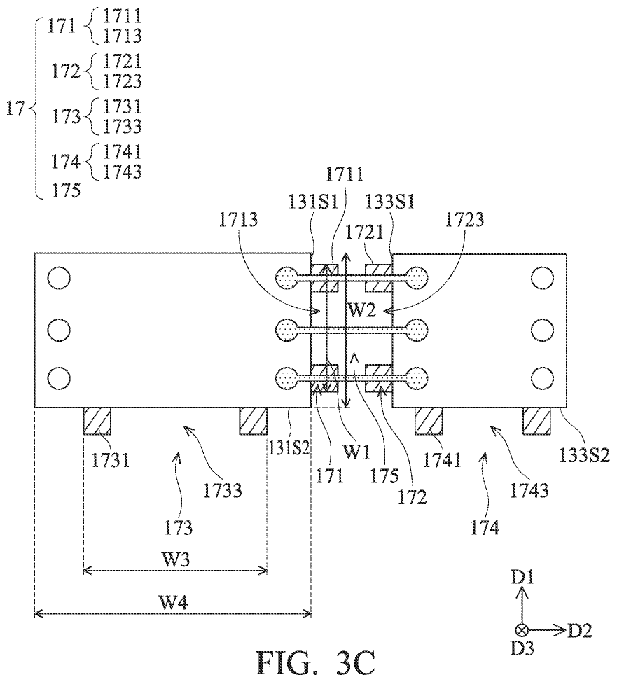

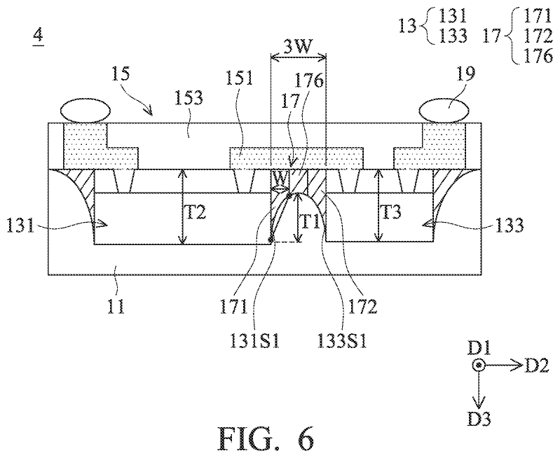

The anchor structure 17 may include a first anchor structure 171 disposed between the first electronic unit 131 and the second electronic unit 133. In some embodiments, the anchor structure 17 further includes a second anchor structure 172 disposed between the first electronic unit 131 and the second electronic unit 133, and an opening 175 between the first anchor structure 171 and the second anchor structure 172. The opening 175 exposes the surface of the protective layer 11 and spatially separates the first anchor structure 171 and the second anchor structure 172, as shown in FIG. 1, but the present disclosure is not limited thereto. In the embodiment in which the anchor structure 17 includes the opening 175, the first conductive layer 151 may be in contact with the surface of the protective layer 11 in the opening 175. For example, in the embodiment shown in FIG. 1, the first conductive layer 151 may contact at least part of the surface of the first electronic unit 131, at least part of the surface of the second electronic unit 133, at least part of the surface of the anchor structure 17, and at least part of the surface The surface of protective layer 11. In some embodiments, the anchor structure 17 may include a connecting portion 176 connecting the first anchor structure 171 and the second anchor structure 172 (as shown in FIGS. 3B and 6). In the embodiment in which the anchor structure 17 has the connecting portion 176, the first conductive layer 151 may contact at least part of the surface of the first electronic unit 131, at least part of the surface of the second electronic unit 133, at least part of the surface of the anchor structure 17 but not contact the surface of the protective layer 11, as shown in FIG. 6. In some embodiments, the anchor structure 17 may independently include materials with Young's modulus between 1000 Mpa and 20000 Mpa. In some embodiments, the first insulating layer 1315 and the second insulating layer 1317, respectively, may include materials with a coefficient of linear thermal expansion (CTE) between 3 and 60 ppm/K. In other embodiments, the anchor structure 17 may include materials with a coefficient of linear thermal expansion (CTE) between 3 and 10 ppm/K. The materials included in the anchor structure 17 may be insulating materials. Examples of the insulating materials may include, but not limited to, epoxy resins, silicone resins, and combinations thereof. In some embodiments, the anchor structure 17 may include heat dissipation materials or heat dissipation particle fillers to assist the chip units in the first electronic unit 131 and the second electronic unit 133 to dissipate heat, or to assist in conducting heat generated by the chip units in the first electronic unit 131 and the second electronic unit 133 to the connecting member 15. Examples of the heat dissipation materials may include, but not limited to, siloxane resin or graphite. Examples of the heat dissipation particle fillers may include, but not limited to, aluminum oxide or boron nitride.

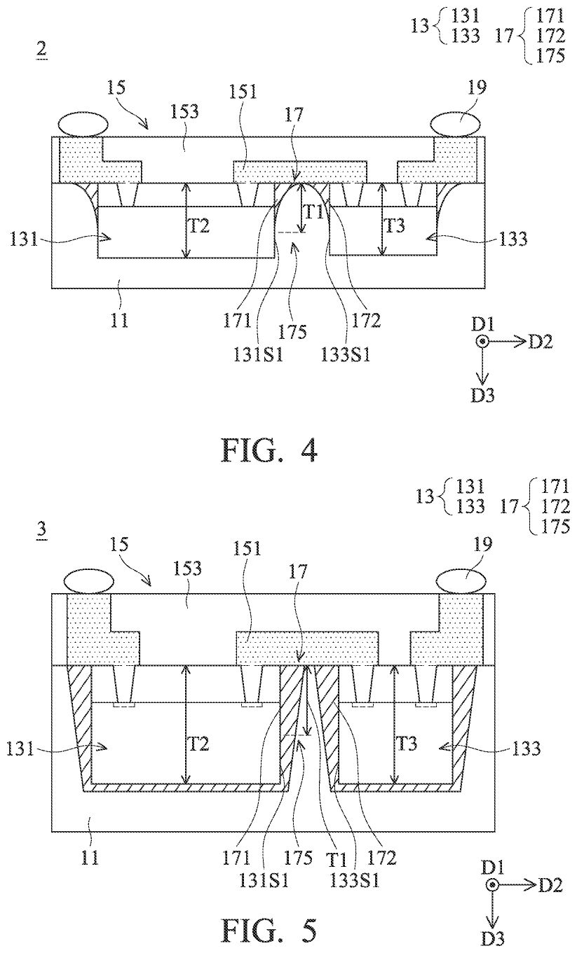

FIGS. 3A to 3C are schematic diagrams illustrating the configuration of the anchor structure 17 in the electronic device according to the embodiment of the present disclosure. FIG. 4 illustrates a cross-sectional schematic view of an electronic device 2 according to another embodiment of the present disclosure. FIG. 5 illustrates a cross-sectional schematic view of an electronic device 3 according to another embodiment of the present disclosure. FIG. 6 illustrates a cross-sectional schematic view of an electronic device 4 according to another embodiment of the present disclosure. The relationship between the anchor structure 17 and the electronic unit 13 is further illustrated below in conjunction with FIGS. 1, 4, 5, and 6, and FIGS. 3A to 3C. As shown in FIGS. 3A to 3C, the first electronic unit 131 has a first side 131S1 extending in the first direction D1 and a second side 131S2 extending in the second direction D2 perpendicular to the first direction D1, and the first side 131S1 is connected to the second side 131S2. The second electronic unit 133 has a first side 133S1 extending in the first direction D1 and a second side 133S2 extending in the second direction D2, and the first side 133S1 is connected to the second side 133S2. The first side 131S1 of the first electronic unit 131 is opposite to the first side 133S1 of the second electronic unit 133.

The anchor structure 17 in the electronic device 1 and the electronic device 2 is further described below in conjunction with FIG. 3A, FIG. 1, and FIG. 4.

In the embodiment shown in FIG. 3A, the anchor structure 17 includes a first anchor structure 171, a second anchor structure 172, and an opening 175. The first anchor structure 171 and the second anchor structure 172 extend along the first direction D1 and are disposed between the first electronic unit 131 and the second electronic unit 133. The first anchor structure 171 is in direct contact with the first side 131S1 of the first electronic unit 131, and the second anchor structure 172 is in direct contact with the first side 133S1 of the second electronic unit 133. The opening 175 is between the first anchor structure 171 and the second anchor structure 172 to spatially separate the first anchor structure 171 and the second anchor structure 172 and expose a part of the surface of the protective layer 11. In some embodiments, the opening 175 may have inclined sidewalls, as shown in FIG. 1, but the present disclosure is not limited thereto. In some embodiments, the opening 175 may have concave curved sidewalls, as shown in FIG. 4, but the present disclosure is not limited thereto. In other embodiments, the opening 175 may have convex curved sidewalls. When the opening 175 has curved sidewalls (concave curved sidewalls or convex curved sidewalls), the risk of breaking of the protective layer 11 due to the first anchor structure 171 and/or the second anchor structure 172 can be reduced or avoided or the problem of excessive stress in the contact area between the protective layer 11 and the first anchor structure 171 and/or the second anchor structure 172 due to the mismatch in the coefficient of linear thermal expansions between the protective layer 11 and the first anchor structure 171 and/or the second anchor structure 172 can be reduced.

The first anchor structure 171 and the second anchor structure 172 can expose the top surface of the chip unit 1311 in the first electronic unit 131 and/or the chip unit in the second electronic unit 133, as shown in FIG. 1 and FIG. 4, but the present disclosure is not limited thereto. In other embodiments, the first anchor structure 171 and the second anchor structure 172 may extend from the sides of the first electronic unit 131 and/or the second electronic unit 133 to cover the top surfaces of the first electronic unit 131 and/or the second electronic unit 133, as shown in FIG. 5.

FIG. 5 illustrates a cross-sectional schematic view of an electronic device 3 according to another embodiment of the present disclosure. As shown in FIG. 5, the electronic device 3 includes a protective layer 11, an electronic unit 13, a connecting member 15, and an anchor structure 17. The anchor structure 17 includes a first anchor structure 171 and a second anchor structure 172. The first anchor structure 171 and the second anchor structure 172 extend along the first direction D1 and are disposed between the first electronic unit 131 and the second electronic unit 133. The first anchor structure 171 is in direct contact with the first side 131S1 of the first electronic unit 131, extends from the first side 131S1 to the opposite side of the first side 131S1 and covers the top surface of the chip unit 1311 in the first electronic unit 131. The second anchor structure 172 is in direct contact with the first side 133S1 of the second electronic unit 133, extends from the first side 133S1 to the opposite side of the first side 133S1 and covers the top surface of the chip unit in the second electronic unit 133. The protective layer 11, the electronic unit 13, and the connecting member 15 in the electronic device 3 are substantially similar to or the same as the protective layer 11, the electronic unit 13, and the connecting member 15 in the electronic devices 1 and 2. According to some embodiments, the anchor structure 17 may include heat dissipation particles so as to have a good heat dissipation effect. For example, the thermal conductivity of the anchor structure 17 is greater than or equal to 0.35 W/m*K and less than or equal to 7 W/m*K, but not limited thereto. According to some embodiments, the thermal conductivity of the anchor structure 17 may be greater than that of the protective layer 11, for example, the thermal conductivity of the anchor structure 17 is 3 W/m*K, which is greater than the thermal conductivity of 0.2 W/m*K of the protective layer 11, but not limited thereto.

In the embodiment shown in FIG. 3A, the anchor structure 17 further includes a third anchor structure 173 and a fourth anchor structure 174. The third anchor structure 173 is in direct contact with the second side 131S2 of the first electronic unit 131, and the fourth anchor structure 174 is in direct contact with the second side 133S2 of the second electronic unit 133. In some embodiments, the side surfaces of the third anchor structure 173 which is not in direct contact with the second side 131S2 of the first electronic unit 131 and the side surfaces of the fourth anchor structure 174 which is not in direct contact with the second side 133S2 of the second electronic unit 133 may be inclined sides or curved sides. When the side surfaces of the third anchor structure 173 which is not in direct contact with the second side 131S2 of the first electronic unit 131 and the side surfaces of the fourth anchor structure 174 which is not in direct contact with the second side 133S2 of the second electronic unit 133 are curved sides, the risk of breaking of the protective layer 11 due to the third anchor structure 173 and/or the fourth anchor structure 174 can be reduced or avoided or the problem of excessive stress in the contact area between the protective layer 11 and the third anchor structure 173 and/or the fourth anchor structure 174 due to the mismatch in the coefficient of linear thermal expansions between the protective layer 11 and the third anchor structure 173 and/or the fourth anchor structure 174 can be reduced.

The anchor structure 17 in the electronic device 4 is further described below in conjunction with FIG. 3B and FIG. 6.

In the embodiment shown in FIG. 3B and FIG. 6, the anchor structure 17 includes a first anchor structure 171, a second anchor structure 172, and a connecting portion 176. The connecting portion 176 is between the first electronic unit 131 and the second electronic unit 133 and connects the first anchor structure 171 and the second anchor structure 172. The thickness of the connecting portion 176 is smaller than that of the first anchor structure 171 and the second anchor structure 172. In some embodiments, the connecting portion 176 may be combined with the first anchor structure 171 and the second anchor structure 172 to form a recessed portion having inclined sidewalls or curved sidewalls. FIG. 6 illustrates an aspect in which the connecting portion 176 is combined with the first anchor structure 171 and the second anchor structure 172 to form a recessed portion having curved sidewalls. In the embodiment shown in FIG. 6, the connecting portion 176, the first anchor structure 171 and the second anchor structure 172 have the same width in the second direction D2. When the side of the first anchor structure 171 which is in direct contact with the first side 131 S1 of the first electronic unit 131 and the side of the first anchor structure 171 which is in direct contact with the connecting portion 176 directly contact the side are connected with a concave curved surface, the connecting portion 176 is combined with the first anchor structure 171 and the second anchor structure 172 to form a recessed portion having curved sidewalls, as shown in FIG. 6. In another embodiment, when the side of the first anchor structure 171 which is in direct contact with the first side 131S1 of the first electronic unit 131 and the side of the first anchor structure 171 which is in direct contact with the connecting portion 176 directly contact the side are connected with a inclined plane surface, the connecting portion 176 is combined with the first anchor structure 171 and the second anchor structure 172 to form a recessed portion having inclined sidewalls. In this embodiment, the anchor structure 17 is located between the protective layer 11 and the connecting member 15, so that the connecting member 15 is not in contact with the surface of the protective layer 11. In the embodiment shown in FIG. 3B, the anchor structure 17 further includes a third anchor structure 173 and a fourth anchor structure 174. The third anchor structure 173 is in direct contact with the second side 131S2 of the first electronic unit 131, and the fourth anchor structure 174 is in direct contact with the second side 133S2 of the second electronic unit 133. The third anchor structure 173 and the fourth anchor structure 174 in this embodiment have structures and advantages similar to those of the third anchor structure 173 and the fourth anchor structure 174 described with reference to FIG. 3A. The description thereof will not be repeated here.

In other embodiments, each of the first anchor structure 171 to the fourth anchor structure 174 may include a plurality of sub-anchor structures. FIG. 3C is a schematic diagram illustrating the configuration of the anchor structure 17 in the electronic device according to another embodiment of the present disclosure. In the embodiment shown in FIG. 3C, the first anchor structure 171 may include two first sub-anchor structures 1711 and a first gap 1713 disposed between the two first sub-anchor structures 1711. The structures 1711 are spatially separated by the first gap 1713. The second anchor structure 172 may include two second sub-anchor structures 1721 and a second gap 1723 disposed between the two second sub-anchor structures 1721. The two second sub-anchor structures 1721 are spatially separated by the second gap 1723. The third anchor structure 173 may include two third sub-anchor structures 1731 and a third gap 1733 disposed between the two third sub-anchor structures 1731. The two third sub-anchor structures 1731 are spatially separated by the third gap 1733. The fourth anchor structure 174 may include two fourth sub-anchor structures 1741 and a fourth gap 1743 disposed between the two fourth sub-anchor structures 1741. The two fourth sub-anchor structures 1741 are spatially separated by the fourth gap 1743. Although FIG. 3C discloses an aspect in which each of the first anchor structure 171 to the fourth anchor structure 174 includes a plurality of sub-anchor structures, the present disclosure is not limited thereto. In some embodiments, at least one of the first anchor structure 171 to the fourth anchor structure 174 has a structure similar to the anchor structure described above in connection with FIG. 3A and/or FIG. 3B (excluding sub-anchor structures). Although FIG. 3C discloses that the first anchor structure 171 includes two first sub-anchor structures 1711 and one first gap 1713, the second anchor structure 172 includes two second sub-anchor structures 1721 and one second gap 1723, the third anchor structure 173 includes two third sub-anchor structures 1731 and one third gap 1733, and the fourth anchor structure 174 include two fourth sub-anchor structures 1741 and one fourth gap 1743, but the present disclosure is not limited thereto. In some embodiments, at least one anchor structure of the first anchor structure 171 to the fourth anchor structure 174 may include three or more sub-anchor structures and two or more gaps.

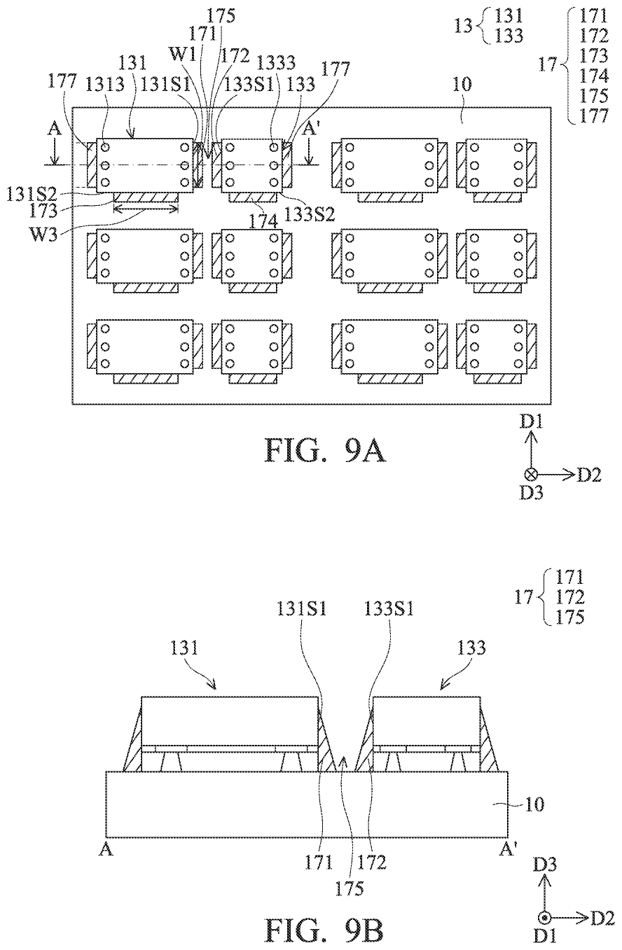

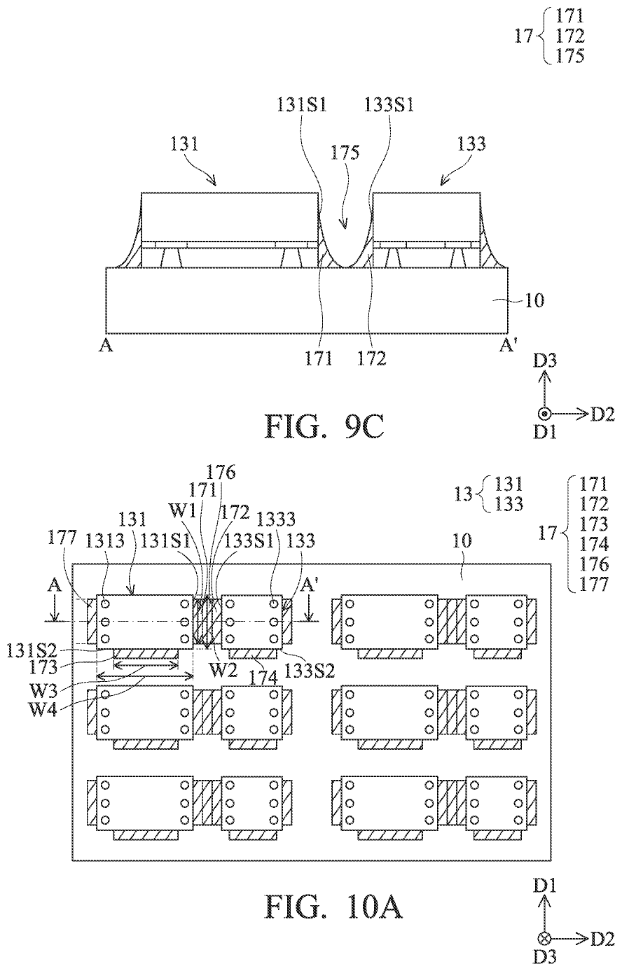

Although FIGS. 3A to 3C disclose an aspect in which the anchor structure 17 includes the first anchor structure 171 to the fourth anchor structure 174, the present disclosure is not limited thereto. In some embodiments, the anchor structure 17 may only include the first anchor structure 171. In other embodiments, the anchor structure 17 may only include the first anchor structure 171 and one of the second anchor structure 172 to the fourth anchor structure 174. In other embodiments, the anchor structure 17 may further include other anchor structures 177 parallel to the first anchor structure 171 and the second anchor structure 172 but not disposed between the first electronic unit 131 and the second electronic unit 133, as shown in FIG. 9A.

The first anchor structure 171 is further described below with reference to FIGS. 3A to 3C again. The side of the first anchor structure 171 in contact with the first side 131S1 has a first width W1 in the first direction D1, and the first side 131S1 of the first electronic unit 131 has a second width W2 in the first direction D1. The first width W1 and the second width W2 conform to the following formula.

0.2≤W1/W2<1

Furthermore, the first width W1 and the second width W2 conform to the following formula.

0.2≤W1/W2<0.8

When the width of the side of the first anchor structure 171 contacts the first side 131S1 of the first electronic unit 131 and the width of the first side 131S1 of the first electronic unit 131 conform to the above formula, the first anchor structure 171 disposed between the first electronic unit 131 and the second electronic unit 133 can anchor the first electronic unit 131 without greatly increasing the manufacturing cost of the electronic device. The ratio between the width of the side of the second anchor structure 172 which is in contact with the first side 133S1 of the second electronic unit 133 and the width of the first side 133S1 of the second electronic unit 133 and the advantages thereof are similar with the ratio between the width of the side of the first anchor structure 171 which is in contact with the first side 131S1 of the first electronic unit 131 and the width of the first side 131S1 of the first electronic unit 131 and the advantages thereof. The description thereof will not be repeated here.

In some embodiments, the third anchor structure 173 may have a third width W3 in the second direction D2, and the second side 131S2 of the first electronic unit 131 may have a fourth width W4 in the second direction D2. The third width W3 and the fourth width W4 conform to the following formula.

0.2≤W3/W4<1

Furthermore, the third width W3 and the fouth width W4 conform to the following formula:

0.2≤W3/W4<0.8

When the width of the side of the third anchor structure 173 contacts the second side 131S2 of the first electronic unit 131 and the width of the second side 131S2 of the first electronic unit 131 conform to the above formula, the third anchor structure 173 can anchor the first electronic unit 131 without greatly increasing the manufacturing cost of the electronic device. The ratio between the width of the side of the fourth anchor structure 174 which is in contact with the second side 133S2 of the second electronic unit 133 and the width of the second side 133S2 of the second electronic unit 133 and the advantages thereof are similar with the ratio between the width of the side of the third anchor structure 173 which is in contact with the second side 131S2 of the first electronic unit 131 and the width of the second side 131S2 of the first electronic unit 131 and the advantages thereof. The description thereof will not be repeated here.

Referring to FIG. 1, FIG. 4 and FIG. 6, the first electronic unit 131 may have a second thickness T2 in a third direction D3, wherein the third direction D3 is perpendicular to the first direction D1 and the second direction D2. The second electronic unit 133 may have a third thickness T3 in the third direction D3. The first anchor structure 171 may have a first thickness T1 in the third direction D3. The third direction D3 may be, for example, the normal direction of the electronic device 1. The first thickness T1 refers to the maximum thickness of the first anchor structure 171 in the third direction D3. The second thickness T2 refers to the sum of the thicknesses of the chip unit 1311, the first insulating layer 1315, and the second insulating layer 1317 in the first electronic unit 131 in the third direction D3, and the third thickness T3 refers to the sum of the thicknesses of the chip unit, the first insulating layer, and the second insulating layer in the second electronic unit 133 in the third direction D3. The second thickness T2 may be greater than or equal to the third thickness T3 of the second electronic unit 133, and the first thickness T1 and the second thickness T2 conform to the following formula.

T2/3≤T1≤T2

Furthermore, the first thickness T1 and the second thickness T2 conform to the following formula.

T2/2≤T1≤T2

When the thickness of the first anchor structure 171 and the thickness of the first electronic unit 131 conform to the above formula, the first anchor structure 171 disposed between the first electronic unit 131 and the second electronic unit 133 can anchor the first electronic unit 131 and the second electronic unit 133 without greatly increasing the manufacturing cost of the electronic device. The thicknesses of the second anchor structure 172 to the fourth anchor structure 174 may be similar with that of the first anchor structure 171. The description thereof will not be repeated here.

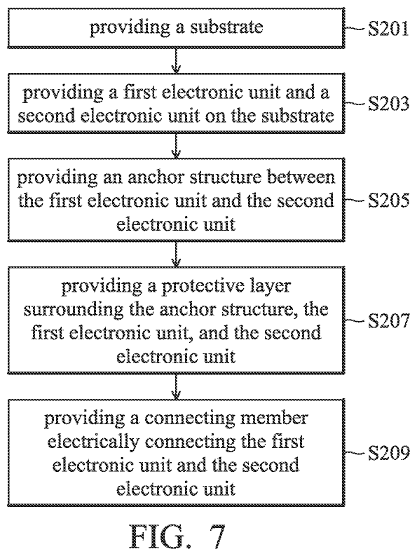

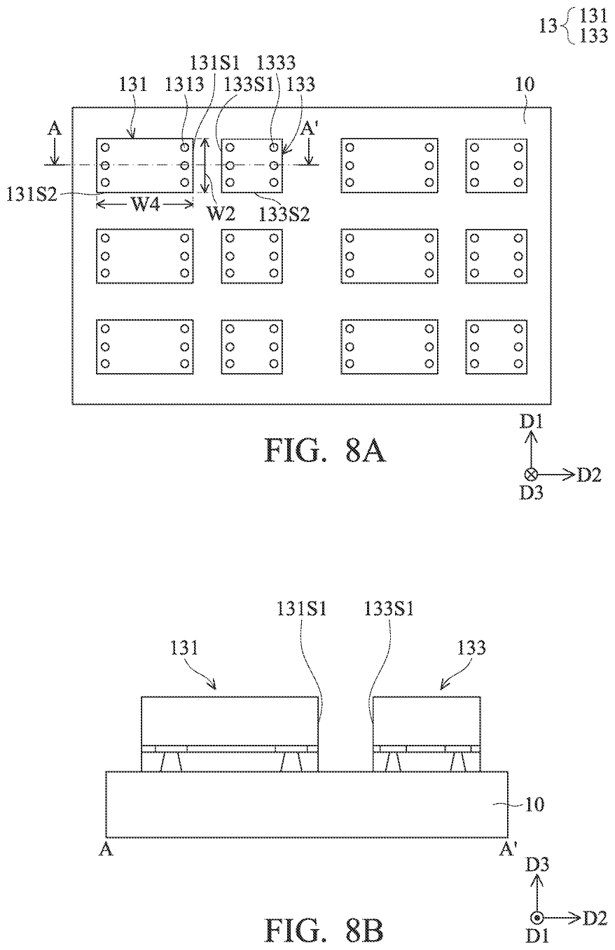

Another aspect of the present disclosure provides a manufacturing method of an electronic device. FIG. 7 is a flowchart illustrating a manufacturing method of an electronic device according to an embodiment of the present disclosure. FIGS. 8A, 9A, and 10A are top schematic views of the electronic device in the middle stage of the manufacturing method of the electronic device according to an embodiment of the present disclosure. FIGS. 8B, 9B, 9C, and 10B to 13 are schematic cross-sectional views of the electronic device in an intermediate stage of the manufacturing method of the electronic device according to an embodiment of the present disclosure. The following illustrates a manufacturing method of an electronic device according to an embodiment of the present disclosure with reference to FIG. 7 and FIGS. 8A to 13.

As shown in FIG. 7, the manufacturing method of the electronic device of the present disclosure includes a step S201 of providing a substrate; a step S203 of providing a first electronic unit and a second electronic unit on the substrate; a step S205 of providing an anchor structure between the first electronic unit and the second electronic unit; a step S207 of providing a protective layer surrounding the anchor structure, the first electronic unit, and the second electronic unit; and a step S209 of providing a connecting member electrically connecting the first electronic unit and the second electronic unit.

The substrate 10 (refer to FIG. 8A and FIG. 8B) provided in the step S201 may include a flexible substrate, a rigid substrate or a combination of the foregoing, but the present disclosure is not limited thereto. In some embodiments, the substrate may be a transparent substrate, a semi-transparent substrate or an opaque substrate. According to some embodiments, the material of the substrate may include glass, quartz, sapphire, ceramic, polyimide (PI), polycarbonate (PC), polyethylene terephthalate (PET), polypropylene (PP), stainless steel, alloy steel, carbon fiber, glass fiber, other suitable materials, or any combination of the foregoing, but the present disclosure is not limited thereto. In some embodiments, the substrate may further include a conductive layer, an insulating layer, a dielectric layer, a display medium layer, an air layer, a vacuum layer, or any combination thereof, but the present disclosure is not limited thereto. FIG. 8A is a top schematic view of the electronic device in the step S203 of the manufacturing method of the electronic device according to an embodiment of the present disclosure. FIG. 8B is a cross-sectional schematic view of the electronic device taken along line A-A′ in FIG. 8A. Referring to FIGS. 8A and 8B, the electronic unit 13 including the first electronic unit 131 and the second electronic unit 133 is provided on the substrate 10 in the step S203. In some embodiments, the step S203 of providing the electronic unit 13 on the substrate includes the step of transferring a plurality of the first electronic unit 131 and the second electronic unit 133 onto the substrate 10. In some embodiments, the electronic units 13 may be provided on the substrate 10 in the form of a matrix.

Referring to FIGS. 8A and 8B, the first electronic unit 131 and the second electronic unit 133 provided on the substrate 10 are spatially separated by a distance. Bonding pads 1313 of the first electronic unit 131 corresponds to bonding pads 1333 of the second electronic unit 133. The first electronic unit 131 has a first side 131S1 and a second side 131S2 connected to the first side 131S1. The first side 131S1 extends along the first direction D1 and has a second width W2 in the first direction D1, and the second side 131S2 extends along the second directions D2 and has a fourth width W4 in the second direction D2. The second electronic unit 133 has a first side 133S1 and a second side 133S2 connected to the first side 133S1. The first side 133S1 extends along the first direction D1 and is opposite to the first side 131S1 of the first electronic unit 131, and the second side edge 131S2 extends along the second direction D2. The width of the first side 133S1 and the width of the second side 133S2 of the second electronic unit 133 may be the same as the width of the first side 131S1 and the second side 131S2. The first electronic unit 131 may have a second thickness T2 along the third direction D3, the second electronic unit 133 may have a third thickness T3 along the third direction D3, and the second thickness T2 of the first electronic unit 131 may be greater than or equal to the third thickness T3 of the second electronic unit 133.

FIG. 9A is a top schematic view of the electronic device in the step S205 of the manufacturing method of the electronic device according to an embodiment of the present disclosure. FIGS. 9B and 9C are cross-sectional schematic views of the electronic device taken along line A-A′ in FIG. 9A. Referring to FIG. 9A, the step S205 of providing the anchor structure between the first electronic unit and the second electronic unit may include providing a first anchor structure 171 and a second anchor structure 172 extending in the first direction D1 and a third anchor structure 173 and a fourth anchor structure 174 extending in the second direction D2. The first anchor structure 171 is in direct contact with the first side 131S1 of the first electronic unit 131, the second anchor structure 172 is in direct contact with the first side 133S1 of the second electronic unit 133, the third anchor structure 173 is in direct contact with the second side 131S2 of the first electronic unit 131, and the fourth anchor structure 174 is in direct contact with the second side 133S2 of the second electronic unit 133, but the present disclosure is not limited thereto. In some embodiments, the step S205 only provides one of the first anchor structure 171 and the second anchor structure 172 between the first electronic unit and the second electronic unit but does not provide the other three of the first anchor structure 171 to the fourth anchor structure 174. In other embodiments, the step S205 may further include providing other anchor structures 177 parallel to the first anchor structure 171 and the second anchor structure 172 but not disposed between the first electronic unit 131 and the second electronic unit 133. The other anchor structures 177 may be in direct contact with the sides of the first electronic unit 131 and the second electronic unit 133, but the present disclosure is not limited thereto. In some embodiments, the step of providing the anchor structure 17 includes providing an opening 175 extending in the first direction D1 between the first anchor structure 171 and the second anchor structure 172. The first conductive layer 151 is in contact with the surface of the protective layer 11 in the opening 175. The opening 175 has inclined sidewalls, as shown in FIG. 9B, but the present disclosure is not limited thereto. In other embodiments, the opening 175 may have curved sidewalls, as shown in FIG. 9C.

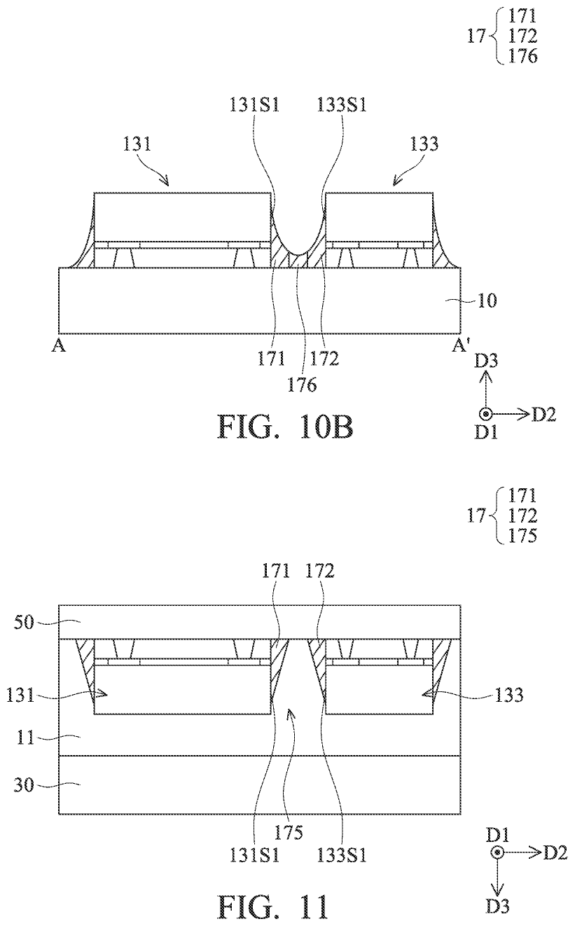

FIG. 10A is a top schematic view of the electronic device in the step S205 of the manufacturing method of the electronic device according to another embodiment of the present disclosure. FIG. 10B is a cross-sectional schematic view of the electronic device taken along line A-A′ in FIG. 10A. The difference between the embodiment shown in FIG. 10A and the embodiment shown in FIG. 9A is that, in the embodiment shown in FIG. 10A, instead of the opening 175, the anchor structure 17 includes a connecting portion 176 between the first anchor structure 171 and the second anchor structure 172 and connecting the first anchor structure 171 and the second anchor structure 172. The thickness of the connecting portion 176 is smaller than that of the first anchor structure 171 and the second anchor structure 172. In some embodiments, the connecting portion 176 may be combined with the first anchor structure 171 and the second anchor structure 172 to form a recessed portion having inclined sidewalls or curved sidewalls, as shown in FIG. 10B.

In some embodiments, the first anchor structure 171 to the fourth anchor structure 174 of the anchor structure 17 and other anchor structures 177 may be formed simultaneously in the step S205. The step S205 of providing the anchor structure 17 may include using a needle coating process, an ink-jet printing coating process, a screen printing coating process, a relief/gravure coating printing coating process, a transfer printing coating process, a chemical vapor deposition (CVD) process, a physical vapor deposition (PVD) process, an atomic layer deposition (ALD) process, a high density plasma chemical vapor deposition (HDPCVD) process, other suitable methods or combinations thereof, but the present disclosure is not limited thereto. In some embodiments, the step S205 of providing the anchor structure 17 may include performing a grinding process or a coating process and an etching process after covering the anchor structure 17 on the first electronic unit 131 and the second electronic unit 133 by thermocompression bonding, but the present disclosure is not limited thereto. In some embodiments, the material used to form the anchor structure 17 may include a material with a Young's modulus between 1000 MPa and 20000 MPa. In some embodiments, the material used to form the anchor structure 17 may include a material with a coefficient of linear thermal expansion (CTE) between 3 and 60 ppm/K. In further embodiments, the material used to form the anchor structure 17 may include a material with a coefficient of linear thermal expansion (CTE) between 3 and 10 ppm/K. Insulating materials may be used to form the anchor structure 17. In some embodiments, examples of the insulating materials may include, but are not limited to, epoxy resins, silicone resins, and combinations thereof. The positional relationship, the width ratio and the thickness ratio between the anchor structure 17 and the first electronic unit 131 and the second electronic unit 133 provided in step S205 are as described above. The description thereof will not be repeated here.

FIGS. 11 to 13 are cross-sectional schematic views of the electronic device in the steps S207 and S209 of the manufacturing method of the electronic device according to an embodiment of the present disclosure. FIG. 11 illustrates an aspect in which the step S207 is performed on the structure shown in FIG. 9B as an example, but the present disclosure is not limited thereto. In some embodiments, the step S207 may be performed on the structure shown in FIG. 9C or FIG. 10B. In the step S207, the protective layer 11 is provided on the substrate 10 on which the anchor structure 17, the first electronic unit 131 and the second electronic unit 133 are formed. The protective layer 11 surrounds the anchor structure 17, the first electronic unit 131 and the second electronic unit 133. More specifically, the protective layer 11 is in direct contact with the side of the anchor structure 17, at least part of the side of the first electronic unit 131 and at least part of the side of the second electronic unit 133. By directly contacting the at least part of the side of the first electronic unit 131 and the at least part of the side of the second electronic unit 133, the protective layer 11 can reduce the influence of moisture and oxygen in the environment on the electronic unit 13. Therefore, the service life and reliability of the electronic unit 13 can be improved. In some embodiments, the protective layer 11 may be formed of any material used as an encapsulation material. In some embodiments, the protective layer 11 may comprise epoxy resins. In some embodiments, the step S207 of providing the protective layer 11 may include forming the protective layer 11 using a dispensing process, an injection molding process, other suitable methods, or a combination thereof. The step S209 may be performed after the step S207. The step S209 of providing the connecting member 15 electrically connecting the first electronic unit 131 and the second electronic unit 133 includes the steps of forming a photoresist material layer 50, forming an insulating layer 153, and filling conductive material. The step of forming the photoresist material layer 50 includes forming a carrier 30 to obtain an intermediate structure. In the intermediate structure, the first electronic unit 131, the second electronic unit 133, the anchor structure 17 and the protective layer 11 are between the carrier 30 and the substrate 10. Remove the substrate 10 after inverting the intermediate structure and form the photoresist material layer 50 on the carrier board 30. The first electronic unit 131, the second electronic unit 133, the anchor structure 17 and the protective layer 11 are located between the carrier board 30 and the photoresist material layer 50, as shown in FIG. 11. The photoresist material layer 50 may be formed by a heat press lamination process, a spin coating process, a spinless coating process, an ink-jet printing coating process, other suitable methods or combinations thereof, but the present disclosure is not limited thereto.

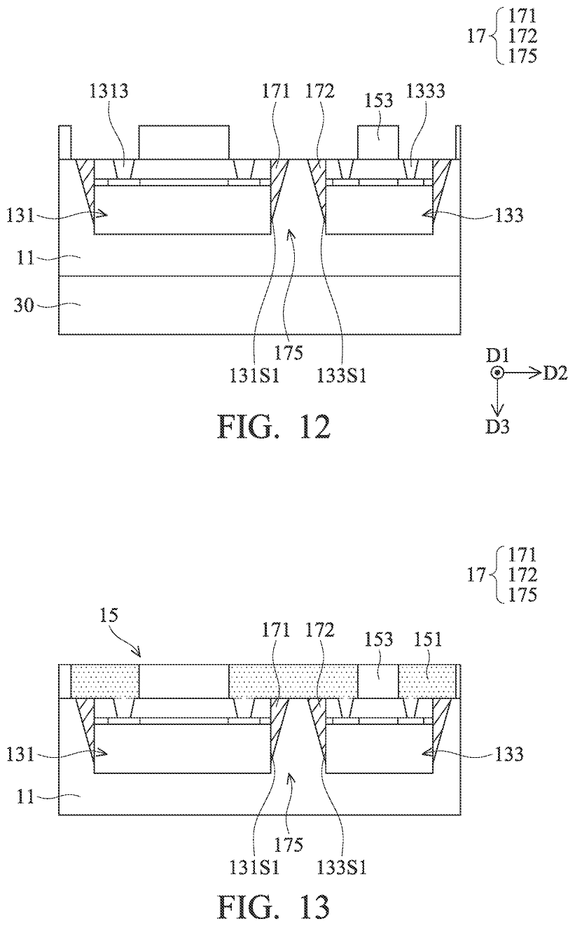

Forming the insulating layer 153 includes steps of patterning the photoresist material layer 50 to expose the bonding pads 1313 of the first electronic unit 131, the bonding pads 1333 of the second electronic unit 133, and the surface of the anchor structure 17 and curing the patterned photoresist material layer 50 to form the insulating layer 153. The step of patterning the photoresist material layer 50 may include a dry etching process, a wet etching process, and combinations thereof, but the present disclosure is not limited thereto. In some embodiments, the patterned photoresist material layer 50 exposes at least part of the surface of the protective layer 11, as shown in FIG. 12, but the present disclosure is not limited thereto. In other embodiments, the patterned photoresist material layer 50 does not expose the surface of the protective layer 11. The step of curing the patterned photoresist material layer 50 may include a photocuring process, a thermal curing process, and combinations thereof, but the present disclosure is not limited thereto.

The first conductive layer 151 electrically connecting the first electronic unit 131 and the second electronic unit 133 is formed by filling the conductive materials between the insulating layers 153, and the preparation of the connecting member 15 is thereby completed. Manufacture of the electronic device may be completed by removing the carrier board 30 after forming the connecting member 15, as shown in FIG. 13. By providing the anchor structure 17 in the above-mentioned manufacturing method, the position shift, falling off or damage that may be caused to the first electronic unit 131 and/or the second electronic unit 133 during the formation of the protective layer 11 can be avoided or reduced. Therefore, the possibility that the connecting member 15 cannot provide a good electrical connection between the first electronic unit 131 and the second electronic unit 133 due to positional displacement, falling off or damage of the first electronic unit 131 and/or the second electronic unit 133 can be reduced.

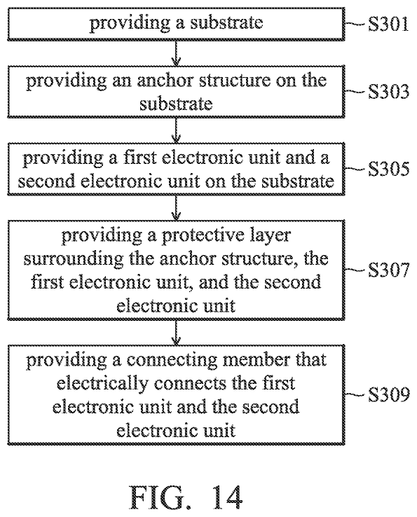

The above provided are only some embodiments of the manufacturing method of the electronic device of the present disclosure. The manufacturing method of the electronic device of the present disclosure is not limited to the order and steps disclosed above. In some embodiments, some steps in the above-described manufacturing method of the electronic device may be omitted. For example, the steps of forming the carrier board 30 and/or inverting the intermediate structure may be omitted in the manufacturing method of the electronic device. In other embodiments, the process order in the manufacturing method of the electronic device of the present disclosure can be changed. FIG. 14 is a flowchart illustrating a manufacturing method of an electronic device according to another embodiment of the present disclosure. FIGS. and 16 are top schematic views of the electronic device in intermediate stages of the manufacturing method of the electronic device according to another embodiment of the present disclosure.

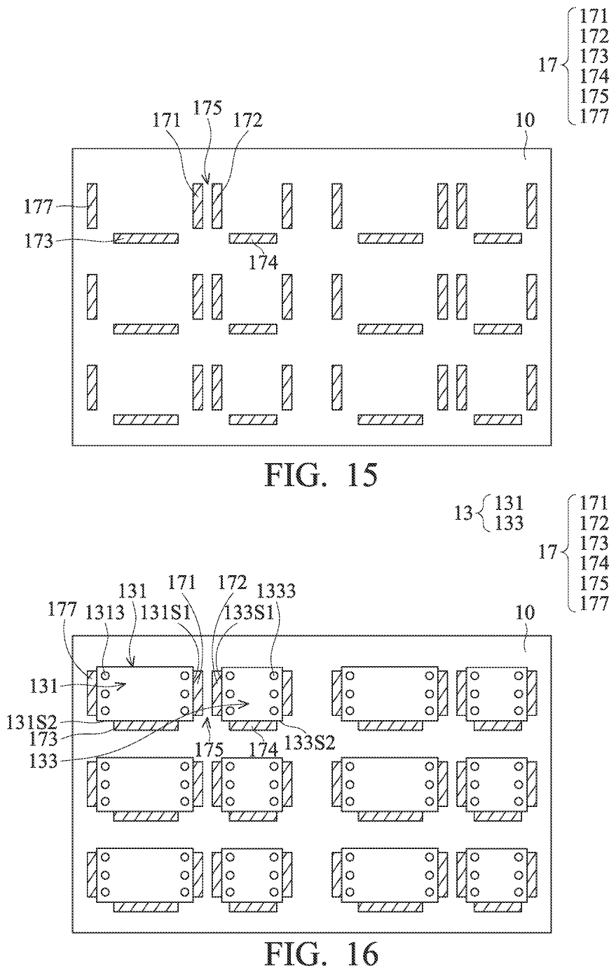

Referring to FIG. 14, a manufacturing method of an electronic device according to another embodiment of the present disclosure may include a step S301 of providing a substrate; a step S303 of providing an anchor structure on the substrate; a step S305 of providing a first electronic unit and a second electronic unit on the substrate; a step S307 of providing a protective layer surrounding the anchor structure, the first electronic unit, and the second electronic unit; and a step S309 of providing a connecting member that electrically connects the first electronic unit and the second electronic unit. The difference between the manufacturing method of the electronic device in this embodiment and the manufacturing method of the electronic device shown in FIG. 7 is that, in the embodiment shown in FIG. 7, the anchor structure is provided after the first electronic unit and the second electronic unit, but in this embodiment, the anchor structure is provided before the first electronic unit and the second electronic unit. Specifically, referring to FIG. 15, FIG. 15 is a top schematic view of the electronic device in the step S303 of the manufacturing method of the electronic device according to an embodiment of the present disclosure. As shown in FIG. 15, The anchor structure 17 may be formed on the substrate 10 before the first electronic unit 131 and the second electronic unit 133 using a needle coating process, an ink-jet printing coating process, a screen printing coating process, a relief/gravure coating printing coating process, a transfer printing coating process, a chemical vapor deposition (CVD) process, a physical vapor deposition (PVD) process, an atomic layer deposition (ALD) process, a high density plasma chemical vapor deposition (HDPCVD) process, other suitable methods or combinations thereof, but the present disclosure is not limited thereto.

FIG. 16 is a top schematic view of the electronic device in the step S305 of the manufacturing method of the electronic device according to an embodiment of the present disclosure. As shown in FIG. 16, the first electronic unit 131 and the second electronic unit 133 are provided on the substrate 10 after the anchor structure 17 is formed. The first anchor structure 171 and the second anchor structure 172 are located between the first electronic unit 131 and the second electronic unit 133. Except to the order of providing the electronic unit 13 and the anchor structure 17, the processes, materials, and advantages used in this embodiment are the same as those in the above-mentioned embodiment. The description thereof will not be repeated here. In this embodiment, the anchor structure 17 can be used to avoid or reduce the positional displacement, falling off or damage of the first electronic unit 131 and/or the second electronic unit 133 during the formation of the protective layer 11 and can be used as an alignment element to avoid or reduce displacement of the electronic unit 13 during the stage of providing the electronic unit 13 on the substrate.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device, comprising:
a protective layer;
a plurality of electronic units disposed in the protective layer, wherein the plurality of electronic units comprise a first electronic unit and a second electronic unit;
a connecting member disposed on the protective layer, wherein the first electronic unit and the second electronic unit are electrically connected through the connecting member; and
at least one anchor structure disposed in the protective layer and located between the first electronic unit and the second electronic unit,
wherein the connecting member has a first conductive layer, and the first conductive layer contacts a surface of the first electronic unit, a surface of the anchor structure and a surface of the protective layer.

2. The electronic device as claimed in claim 1, wherein the first electronic unit comprises:
a chip unit, wherein the chip unit comprises a plurality of bonding pads;
a first insulating layer disposed on the chip unit; and
a second insulating layer disposed between the first insulating layer and the connecting member,
wherein the first insulating layer and the second insulating layer expose the plurality of bonding pads.

3. The electronic device as claimed in claim 1, wherein the first electronic unit has a first side extending in a first direction, and the at least one anchor structure is in direct contact with the first side of the first electronic unit.

4. The electronic device as claimed in claim 3, further comprising another anchor structure disposed between the first electronic unit and the second electronic unit, wherein the second electronic unit has a first side extending in the first direction, and the other anchor structure is in direct contact with the first side of the second electronic unit.

5. The electronic device as claimed in claim 4, further comprising an opening between the at least one anchor structure and the other anchor structure, wherein the first conductive layer is in contact with the surface of the protective layer in the opening and the opening has inclined sidewalls.

6. The electronic device as claimed in claim 4, further comprising an opening between the at least one anchor structure and the other anchor structure, wherein the first conductive layer is in contact with the surface of the protective layer in the opening and the opening has curved sidewalls.

7. The electronic device as claimed in claim 3, wherein the least one anchor structure has a first width W1 in the first direction, the first side of the first electronic unit has a second width W2 in the first direction, and the first width W1 and the second width W2 conforms to the following formula:
0.2≤W1/W2<1.

8. The electronic device as claimed in claim 7, wherein the first width W1 and the second width W2 conforms to the following formula:
0.2≤W1/W2<0.8.

9. The electronic device as claimed in claim 3, wherein the least one anchor structure has a first thickness T1 in a third direction perpendicular to the first direction, the first electronic unit has a second thickness T2 in the third direction, and the first thickness T1 and the second thickness T2 conform to the following formula:
T2/3≤T1≤T2

10. The electronic device as claimed in claim 1, wherein the least one anchor structure comprises a plurality of sub-anchor structures.

11. A manufacturing method of an electronic device, comprising:
providing a substrate;
providing a first electronic unit and a second electronic unit on the substrate;
providing at least one anchor structure between the first electronic unit and the second electronic unit;
providing a protective layer surrounding the at least one anchor structure, the first electronic unit, and the second electronic unit; and
providing a connecting member, wherein the first electronic unit and the second electronic unit are electrically connected through the connecting member.

12. The manufacturing method of an electronic device as claimed in claim 11, wherein the first electronic unit has a first side extending in a first direction, and the at least one anchor structure is in direct contact with the first side of the first electronic unit.

13. The manufacturing method of an electronic device as claimed in claim 12, further comprising providing another anchor structure between the first electronic unit and the second electronic unit, wherein the second electronic unit has a first side extending in the first direction, and the other anchor structure is in direct contact with the first side of the second electronic unit.

14. The manufacturing method of an electronic device as claimed in claim 13, further comprising providing an opening between the at least one anchor structure and the other anchor structure, wherein a first conductive layer of the connecting member is in contact with the surface of the protective layer in the opening and the opening has inclined sidewalls.

15. The manufacturing method of an electronic device as claimed in claim 13, further comprising providing an opening between the at least one anchor structure and the other anchor structure, wherein a first conductive layer of the connecting member is in contact with the surface of the protective layer in the opening and the opening has curved sidewalls.

16. A manufacturing method of an electronic device, comprising:
providing a substrate;
providing at least one anchor structure on the substrate;
providing a first electronic unit and a second electronic unit on the substrate, wherein the at least one anchor structure is between the first electronic unit and the second electronic unit;
providing a protective layer surrounding the at least one anchor structure, the first electronic unit, and the second electronic unit; and
providing a connecting member, wherein the first electronic unit and the second electronic unit are electrically connected through the connecting member.

17. The manufacturing method of an electronic device as claimed in claim 16, wherein the first electronic unit has a first side extending in a first direction, and the at least one anchor structure is in direct contact with the first side of the first electronic unit.

18. The manufacturing method of an electronic device as claimed in claim 16, further comprising providing another anchor structure between the first electronic unit and the second electronic unit, wherein the second electronic unit has a first side extending in the first direction, and the other anchor structure is in direct contact with the first side of the second electronic unit.

19. The manufacturing method of an electronic device as claimed in claim 18, further comprising providing an opening between the at least one anchor structure and the other anchor structure, wherein a first conductive layer of the connecting member is in contact with the surface of the protective layer in the opening and the opening has inclined sidewalls.

20. The manufacturing method of an electronic device as claimed in claim 18, further comprising providing an opening between the at least one anchor structure and the other anchor structure, wherein a first conductive layer of the connecting member is in contact with the surface of the protective layer in the opening and the opening has curved sidewalls.
